(19) United States
(12) Patent Application Publication
(10) Pub. No.: US 2009/0279244 A1
(43) Pub. Date: Nov. 12, 2009

(54) Disk Drive Carrier and Cage Preventing Installation of Incompatible Disk Drives

(75) Inventors: Martin Joseph Crippen, Apex, NC (US); Brian Michael Kerrigan, Cary, NC (US); Charles William Piper, Burlington, NC (US); Brian Alan Trumbo, Apex, NC (US)

Correspondence Address: IBM CORPORATION (SS/NC);c/o STREETS & STEELE, 13831 NORTHWEST FREEWAY, SUITE 355, HOUSTON, TX, 77040, US

(73) Assignee: INTERNATIONAL BUSINESS MACHINES CORPORATION, Armonk, NY (US)

(21) Appl. No.: 12/119,102

(22) Filed: May 12, 2008

(51) Int. Cl. G06F 1/16; H05K 13/00

(52) U.S. Cl. 361/679.33; 29/729

(57) ABSTRACT

An apparatus comprising a disk drive assembly and a disk drive cage for selectively receiving the disk drive assembly. The disk drive assembly includes first and second side rails secured to opposing sides of a disk drive, wherein the first side rail includes a distal end having a distally-opening slot configured to receive a rigid structure, such as a bent portion of the cage, fixedly extending from the disk drive cage. The slot in the first side rail enables the disk drive assembly to distally advance to a fully installed position within the disk drive cage. Incompatible disk drive assemblies do not include such a slot and are prevented from reaching the fully installed position. Preferably the distal end of first side rail extends beyond the distal end of the disk drive.

### BACKGROUND OF THE INVENTION

1. Field of the Invention

The present invention relates to disk drive carriers and cage assemblies used for the installation of disk drives in a computer system.

2. Background of the Related Art

Computer systems are complex inter-related combinations of hardware and software components that rely upon numerous design standards, communication protocols, connecting interfaces, power requirements, thermal management, and proper physical installation and maintenance. A modern computer system must be developed so that each of these hardware and software components will operate properly and reliably. Extensive testing occurs during and after the computer system has been designed and implemented. Redesigns, refinements, improvements, patches, and additions may occur so that the computer system will meet the demands of a particular type of application.

Once a computer system has been fully developed, a system manufacturer may qualify that each of the components will work reliably in that system. For example, a vendor's hard disk drive may be qualified as being fully compatible with their servers, whereas a third party's hard disk drive is outside their control and may or may not work reliably. If the cause of not properly attributed to the installation of the incompatible component, the reputation and/or sales of the system manufacturer may undeservingly suffer. Furthermore, an end user that accidentally or intentionally installs the third party's disk drive may void certain warrantees offered by the system manufacturer.

### BRIEF SUMMARY OF THE INVENTION

One embodiment of the present invention provides an apparatus comprising a disk drive assembly and a disk drive cage for selectively receiving the disk drive assembly. The disk drive assembly includes first and second side rails secured to opposing sides of a disk drive, wherein the first side rail includes a distal end having a distally-opening slot configured to receive a rigid structure fixedly extending from the disk drive cage. The slot in the first side rail enables the disk drive assembly to distally advance to a fully installed position within the disk drive cage.

Another embodiment of the invention provides a method comprising securing a disk drive cage in a chassis or rack having a computer system compatible with certain disk drive assemblies, providing the disk drive cage with an inwardly extending fixed rigid structure positioned to align with disk drive assemblies being installed in disk drive cage, configuring compatible disk drive assemblies to include a distally-opening slot aligned to receive the rigid structure, selectively receiving a compatible disk drive assembly into a fully installed position within the disk drive cage, wherein the distally-opening slot of the compatible disk drive assembly receives the rigid structure, and preventing an incompatible disk drive from being selectively received into a fully installed position within the disk drive cage due to contact with the rigid structure, wherein the incompatible disk drive assembly is not configured with a distally-opening slot aligned to receive the rigid structure.

### BRIEF DESCRIPTION OF THE SEVERAL VIEWS OF THE DRAWINGS

FIG. 1 is a perspective assembly view of a disk drive assembly aligned to be received into a disk drive cage.

FIG. 2 is an alternative perspective view of the disk drive cage showing a rigid structure fixedly extending from the distal end of the cage.

FIG. 3 is a perspective view of the disk drive assembly having been received into a fully installed position within the disk drive cage.

FIG. 4 is a perspective view of the distal end of the disk drive assembly in the fully installed position within the disk drive cage.

FIG. 5 is a perspective view of the distal end of a disk drive cage preventing an incompatible disk drive assembly from advancing to a fully installed position.

FIG. 6 is a perspective view of the distal end of the disk drive cage having received a compatible disk drive assembly in the fully installed position.

FIG. 7 is a perspective view of a cage having a complex rigid structure that is stepped.

FIG. 8 is a perspective view of the same cage as in FIG. 7, with the same disk drive assembly in a proper orientation for installation.

### DETAILED DESCRIPTION OF THE INVENTION

One embodiment of the present invention provides an apparatus comprising a disk drive assembly and a disk drive cage for selectively receiving the disk drive assembly. The disk drive assembly includes first and second side rails secured to opposing sides of a disk drive, wherein the first side rail includes a distal end having a distally-opening slot configured to receive a rigid structure fixedly extending from the disk drive cage. The slot in the first side rail enables the disk drive assembly to distally advance to a fully installed position within the disk drive cage. Preferably the distal end of first side rail extends beyond the distal end of the disk drive. The disk drive may be any type of mass storage medium, such as a hard disk drive.

A disk drive cage is a structure for receiving the disk drive assembly, which housing may be a minimal structure for securing and positioning the disk drive assembly. A preferred disk drive cage at least includes opposing channels for slidably receiving the first and second side rails of the disk drive assembly. The rigid structure extending from the cage is optionally a bent portion of the cage, but could also be a separate element secured to the cage by, for example, fasteners or welding.

Optionally, the disk drive assembly may have first and second side rails that are part of a disk drive carrier having other features, such as a latch or vibration damping elements. Accordingly, the disk drive assembly may include a first latch member that aligns with a mating latch member of the disk drive cage when the disk drive assembly reaches the fully installed position. A variety of latch members and designs may be used for latching the disk drive assembly within the cage. A disk drive assembly may also include a handle to facilitate insertion and removal from the disk drive cage.

The second side rail may be implemented for one or more purposes, such as alignment of the disk drive within the cage, attachment of a handle or latch, and vibration damping. In optional embodiments, the second side rail may include a distal end having a slot configured to receive a rigid structure fixedly extending from the disk drive cage, and wherein the slot in the second side rail enables the disk drive assembly to advance to a fully installed position within the disk drive cage. Accordingly, the second side rail may interact with a rigid structure of the cage in the same manner as the first side rail. Furthermore, both the first and second side rails may extend beyond the distal end of the disk drive, and optionally may be inwardly angled to facilitate easy alignment and insertion of the disk drive assembly into the cage.

Another embodiment of the invention provides a method comprising securing a disk drive cage in a chassis or rack having a computer system compatible with certain disk drive assemblies, providing the disk drive cage with an inwardly extending fixed rigid structure positioned to align with disk drive assemblies being installed in disk drive cage, configuring compatible disk drive assemblies to include a distally-opening slot aligned to receive the rigid structure, selectively receiving a compatible disk drive assembly into a fully installed position within the disk drive cage, wherein the distally-opening slot of the compatible disk drive assembly receives the rigid structure, and preventing an incompatible disk drive from being selectively received into a fully installed position within the disk drive cage due to contact with the rigid structure, wherein the incompatible disk drive assembly is not configured with a distally-opening slot aligned to receive the rigid structure. The inability to fully install an incompatible disk drive will alert the user that the disk drive assembly is incompatible.

The method may optionally further comprising selectively latching a disk drive assembly into the disk drive cage only when the disk drive assembly reaches the fully installed position. For example, the disk drive assembly may be configured with a latch element that is positioned on the disk drive assembly so that it can only engage a mating latch element on the disk drive cage when the disk drive assembly is in the fully installed position. Since the assembly can only reach the fully installed position if the first side rail has a distally-opening slot configured to receive a rigid structure, the inability to latch the disk drive assembly into the cage will further alert the user that the disk drive assembly is incompatible.

In yet another embodiment, the method step of configuring compatible disk drive assemblies to include a distally-opening slot further includes securing first and second side rails to opposing sides of a compatible disk drive, wherein the first side rail includes a distal end having a distally-opening slot configured to receive the rigid structure as the disk drive assembly advances to the fully installed position. The first and second side rails are preferably elements of a disk drive carrier.

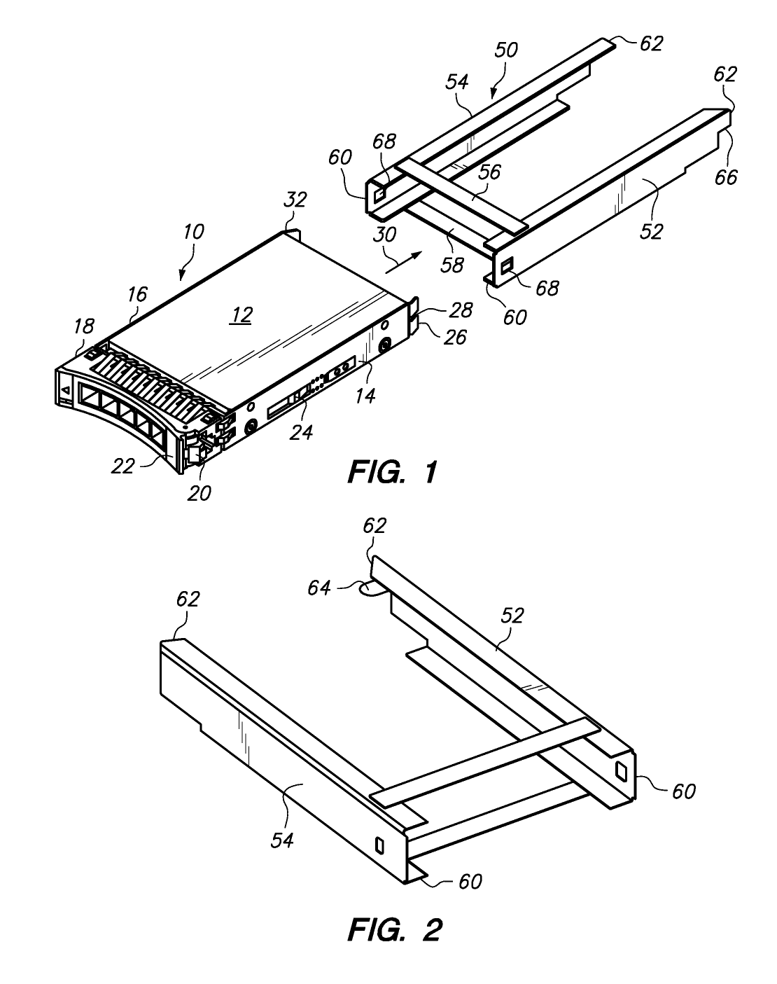

FIG. 1 is a perspective assembly view of a disk drive assembly 10 aligned to be received into a disk drive cage 50. In practice, the disk drive cage 50 would typically be secured in a chassis along with other components. For example, a plurality of disk drive cages may secured side-by-side in a common chassis. However, the present figure focuses on the use of a single cage without showing a chassis or other components, although a disk drive cage would not be used alone in practice.

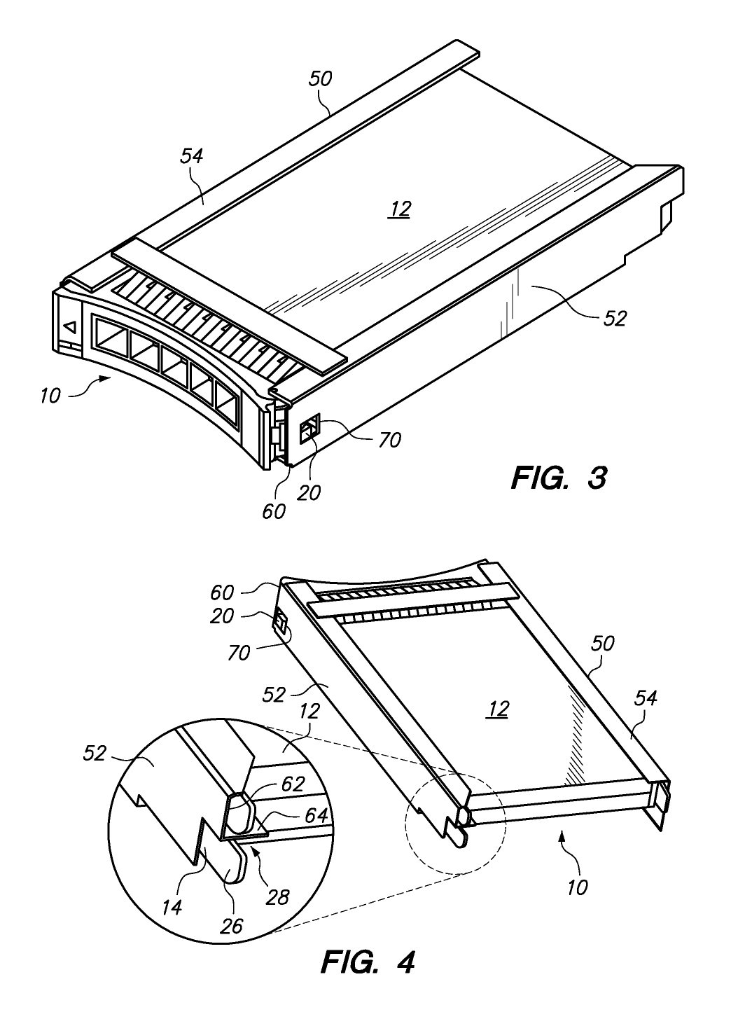

The disk drive cage 50 includes a first channel or side wall 52 and a second channel or side wall 54 secured in a spaced-apart, parallel arrangement by top and bottom spacer bars 56, 58. Each channel 52, 54 may be described as having a proximal end 60 and a distal end 62. The first channel 52 has a distal end 60 with a rigid structure 64 extending inwardly (See also FIG. 2) between the channels or side walls 52, 54. As shown, the rigid structure 64 is a tab, suitable formed by inwardly bending a cut portion of the channel 52 about a line 66. The rigid structure 64 is aligned with the channel 52. Also shown is a latch element 68 formed near the proximal end 60 of each channel 52, 54 for receiving a latch element of the disk drive assembly 10 when the assembly is received into a fully installed position (See FIG. 3).

The disk drive assembly 10 includes a disk drive 12 secured between a first side rail 14 and a second side rail 16. In the embodiment of FIG. 1, the first and second side rails 14, 16, along with a front subassembly 18, are part of a disk drive carrier or tray. The front subassembly 18 is secured to the proximal ends of the first and second side rails 14, 16 and includes a latch member 20, a pivotable latch arm or handle 22 for actuating the latch member 20, and leaf springs 24 for centering the disk drive assembly 10 within the cage 50, damping vibration of the disk drive, and allowing the circulation of cool air over the disk drive 12 during operation.

The first side rail 14 also includes a leaf spring 24 for pressing against the inside surface of first channel 52 so that the disk drive assembly 10 firmly engages the cage 50. The leaf spring 24 and/or other types of features may further provide vibration damping so that the vibration of the disk drive operation does not affect other components of a computer system.

Furthermore, the first side rail 14 has a distal end 26 having a distally-opening slot 28 configured to receive the rigid structure 64 fixedly extending from the disk drive cage 50. For example the slot 28 is aligned with the rigid structure 64 and is wide enough to receive the structure 64 into the slot 28. Accordingly, the slot 28 enables the disk drive assembly 10 to distally advance (see directional arrow 30) to a fully installed position within the disk drive cage (See FIG. 3).

FIG. 2 is an alternative perspective view of the disk drive cage 50 showing the rigid structure 64 fixedly extending from the cage adjacent the distal end 62. It should be noted that the rigid structure 64 is centered with respect to the height of the channel 52 and slot 28 is centered with respect to the height of the side rail 14. With the height of the channel 52 sized to narrowly receive the side rail 14, the slot 28 will generally align with the rigid structure 64. Making the slot 28 somewhat oversized and/or with a tapered profile will assure that the rigid structure 64 is received within the slot 28.

The second side rail 16 may or may not include a similar slot (as discussed later), but is shown here with a distal end 32 extending distally beyond the distal end of the disk drive 12. Suitably, the distal end 26 of the first rail 14 and the distal end 32 of the second rail 16 are angled inwardly to assist with alignment and insertion of the assembly 10 into the channels 52, 54 of the cage 50.

FIGS. 3 and 4 are front and back perspective views of the disk drive assembly 10 having been received into a fully installed position within the disk drive cage 50. Near the proximal end 60 of the first channel 52, a latch member 20 of the disk drive assembly 10 has been received into a latch window 70 formed in the first channel 52. It should be recognized that, for this embodiment, the disk drive assembly 10 cannot be latched into the cage 50 except when the disk drive assembly 10 is in the fully installed position as shown. A similar latch member 20 may be provided to engage a similar latch window 70 in the opposing side rail 54, but is not shown.

FIG. 4 includes an enlarged view of the distal end of the disk drive assembly 10 in the fully installed position within the disk drive cage 50. In particular, the enlarged view shows a distal end 62 of the first channel 52 with the rigid structure 64, in the form of a bent tab, extending inwardly with respect to the cage 50. Because the disk drive assembly 10 has a first side rail 14 with a distal end 26 that includes a distally-opening slot 28, the disk drive assembly 10 has been able to reach a fully installed position. More particularly, the distally-opening slot 28 receives the rigid structure 64 to allow the disk drive assembly 10 to advance into the cage 50 the last distance necessary to reach a fully installed position.

FIG. 5 is a perspective view of the distal end of a disk drive cage 50 preventing an incompatible disk drive assembly 80 from advancing to a fully installed position. The incompatible disk drive assembly 80 includes an incompatible disk drive 82 and a first side rail 84 that extends distally from the distal end of the disk drive 82. Because the first side rail 84 does not include an aligned distally-opening slot, the distal end 86 of the first side rail 84 is blocked by the rigid structure 64 and cannot advance to a fully installed position. In a preferred embodiment, this blocked, not-fully-installed position prevents the incompatible disk drive assembly 80 from being latched into the cage 50. The physical protrusion of the assembly 80 from the front of the cage 50, and/or the inability to latch the assembly 80 into the cage 50 will alert the user that the disk drive assembly 80 is incompatible with the cage 50 and, therefore, incompatible with the associated computer system generally.

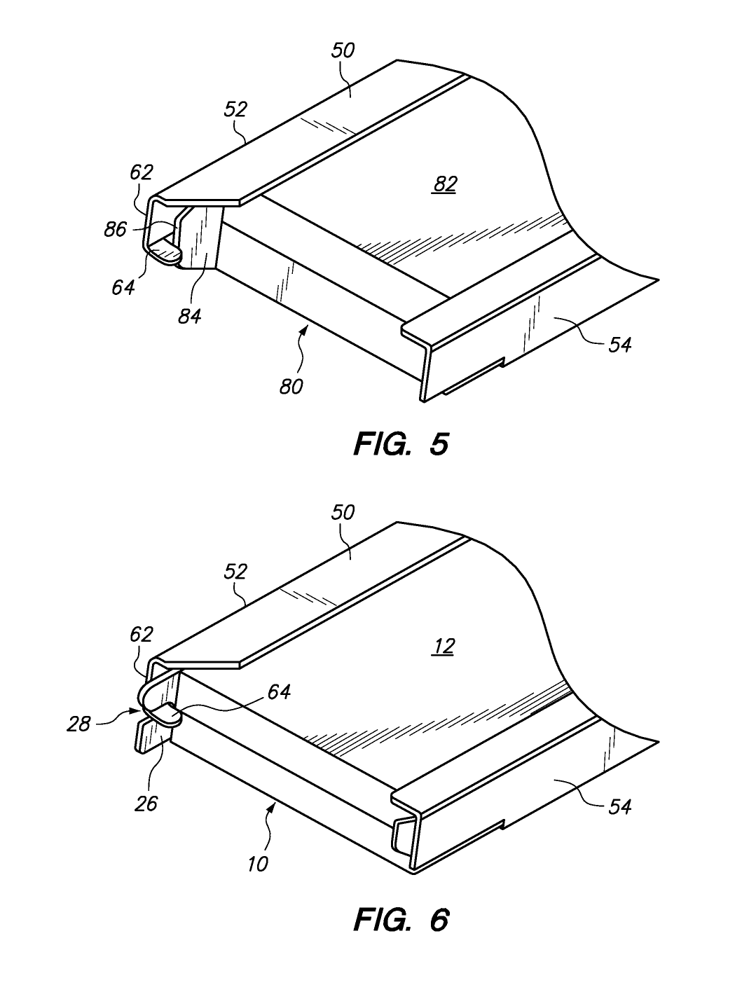

FIG. 6 is a partial perspective view of the distal end of the disk drive cage 50 having received a compatible disk drive assembly 10 in the fully installed position. FIG. 6 is very similar to FIG. 4, but shows a different angle. Accordingly, FIG. 6 shows a compatible disk drive assembly 10 received in a fully installed position for comparison with the incompatible disk drive assembly 80 that cannot be fully installed as shown in FIG. 5. It is the presence or absence of the distally-opening slot 28 that determines whether or not a disk drive assembly can reach the fully installed position. Accordingly, disk drive assemblies that are compatible with the associated computer systems (not shown) should include a first side rail having a distally-opening slot 28 for receiving the rigid structure 64. Incompatible disk drive assemblies should include side rails that prevent the assembly from reaching the fully installed position.

It should be recognized a similar rigid structure may also be formed on the second side channel (i.e., the left side channel instead of the right side channel) or on both of the side channels. Where both side channels have rigid structures, that may either be identically positioned or differently positioned and configured, so long as the combination of positions and configurations aligns with and is received by mating distally-opening slots in a compatible disk drive assembly.

Accordingly, embodiments of the invention are envisioned that provide multiple cage-assembly pairs that are compatible with each other, but other combinations of the same cages and assemblies will be incompatible and prevented from reaching a fully installed position. Therefore, any particular disk drive assembly may only be installed in a specific cage intended for installation of that particular assembly.

Furthermore, while a cage must have at least one rigid structure, the invention encompasses cages having multiple rigid structures. Those multiple rigid structures may be on opposing channels or on the same channel. Where two or more rigid structures extend along the same channel, the distal end of the side rail of a compatible disk drive assembly needs to have a profile that receives the two rigid structures, such as an equal number of slots aligned and sized to receive the rigid structures. Even further, the complementary profiles of the rigid structure and the slot are not limited to narrow, linear profiles. Rather, the complementary profiles may include steps, curves, and other complex two and three dimensional geometric profiles.

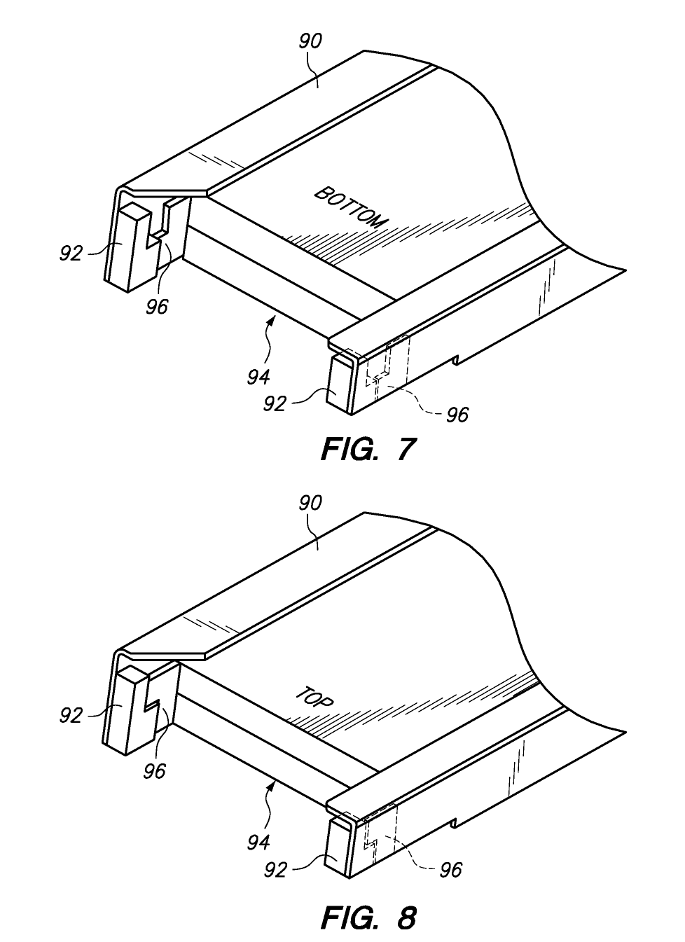

FIG. 7 is a perspective view of a cage 90 having a complex rigid structure 92, optionally on both sides of the cage, that is stepped so that a compatible disk drive assembly can only reach the fully installed position if it has a rail presenting a complementary stepped profile. As shown, the disk drive assembly 94 has a side rail 96 with a stepped profile, but the profile is not presented in a manner to be complimentary to the profile of the structure 92. Accordingly, the disk drive assembly 94 can not reach a fully installed position.

Conversely, FIG. 8 is a perspective view of the same cage 90 receiving the same disk drive assembly 94 which has now been turned over (top side up). As a result, the stepped profile of the first and second side rails 96 fully receives the rigid structure 92 and allows the disk drive assembly 94 to reach a fully installed position within the cage 90. It will be appreciated that this embodiment illustrates how incompatible disk drive assemblies may be prevented from installation and how even compatible disk drive assemblies may be prevented from installation in an improper orientation.

Still further, the invention is not limited to rigid structures extending from the side channels and associated slots on side rails. Rather, rigid structures and distally-opening slots having complementary profiles may be aligned at any position along the distal ends of the cage and disk drive assembly. For example, the rigid structure may extend upward from the bottom of the cage, extend downward from the top of the cage, inward from the sides of the cage, or any combination thereof. An aligned slot must then be provided on the disk drive assembly in order to distinguish compatible and incompatible disk drive assemblies. However, the rigid structures are preferably implemented along the sides because present cages already have opposing side channels that extend to the distal end. While the slots are preferably formed in add-on rails or other add-on structure, the invention may also be implemented as slots formed integrally in the geometry of the disk drive housing.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the invention.

The corresponding structures, materials, acts, and equivalents of all means or steps plus function elements in the claims below are intended to include any structure, material, or act for performing the function in combination with other claimed elements as specifically claimed. The description of the present invention has been presented for purposes of illustration and description, but it not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. An apparatus comprising:
a disk drive assembly including first and second side rails secured to opposing sides of a disk drive; and
a disk drive cage for selectively receiving the disk drive assembly, wherein the first side rail includes a distal end having a distally-opening slot configured to receive a rigid structure fixedly extending from the disk drive cage, and wherein the slot in the first side rail enables the disk drive assembly to distally advance to a fully installed position within the disk drive cage.

2. The apparatus of claim 1, wherein the rigid structure is a bent portion of the cage.

3. The apparatus of claim 1, wherein the disk drive assembly includes a first latch member that aligns with a mating latch member of the disk drive cage when the disk drive assembly reaches the fully installed position

4. The apparatus of claim 1, wherein the second side rail includes a distal end having a slot configured to receive the rigid structure fixedly extending from the disk drive cage, and wherein the slot in the second side rail enables the disk drive assembly to advance to a fully installed position within the disk drive cage.

5. The apparatus of claim 1, wherein the second side rail includes a distal end that does not having a slot configured to receive the rigid structure, and wherein the absence of a slot in the second side rail only prevents the disk drive assembly from advancing to a fully installed position unless the disk drive assembly is oriented with the distally-opening slot of the first side rail aligned to receive the rigid structure.

6. The apparatus of claim 1, wherein the disk drive cage forms opposing channels for slidably receiving the first and second side rails.

7. The apparatus of claim 1, wherein the distal end of first side rail extends beyond the distal end of the disk drive.

8. The apparatus of claim 7, wherein the second side rail has a distal end extending beyond the distal end of the disk drive.

9. The apparatus of claim 8, wherein the distal ends of the first and second side rails are inwardly angled.

10. The apparatus of claim 1, wherein the disk drive is a hard disk drive.

11. An apparatus comprising:
a disk drive cage for selectively receiving the disk drive assembly, wherein the disk drive cage includes a rigid structure fixedly extending from the disk drive cage; and
a disk drive assembly including a distal end having a distally-opening slot configured to receive the rigid structure, and wherein the slot enables the disk drive assembly to distally advance to a fully installed position within the disk drive cage.

12. The apparatus of claim 11, wherein the disk drive assembly includes a first latch member that aligns with a mating latch member of the disk drive cage when the disk drive assembly reaches the fully installed position

13. The apparatus of claim 11, wherein the rigid structure and the slot are configured to prevent the disk drive assembly from distally advancing to the fully installed position unless the disk drive assembly is oriented correctly

14. The apparatus of claim 11, wherein the disk drive is a hard disk drive.

15. The apparatus of claim 11, wherein the rigid structure extends inwardly from along a top or bottom of the disk drive cage.

16. The apparatus of claim 11, wherein the rigid structure is securedly attached to the cage.

17. A method comprising:
securing a disk drive cage in a chassis or rack having a computer system compatible with certain disk drive assemblies;
providing the disk drive cage with an inwardly extending fixed rigid structure positioned to align with disk drive assemblies being installed in disk drive cage;
configuring compatible disk drive assemblies to include a distally-opening slot aligned to receive the rigid structure;
selectively receiving a compatible disk drive assembly into a fully installed position within the disk drive cage, wherein the distally-opening slot of the compatible disk drive assembly receives the rigid structure; and
preventing an incompatible disk drive from being selectively received into a fully installed position within the disk drive cage due to contact with the rigid structure, wherein the incompatible disk drive assembly is not configured with a distally-opening slot aligned to receive the rigid structure.

18. The method of claim 17, further comprising:
selectively latching a disk drive assembly into the disk drive cage only when the disk drive assembly reaches the fully installed position.

19. The method of claim 17, wherein a latch element on the disk drive assembly can only engage a mating latch element on the disk drive cage when the disk drive assembly is in the fully installed position.

20. The method of claim 17, wherein the step of configuring compatible disk drive assemblies to include a distally-opening slot includes securing first and second side rails to opposing sides of a compatible disk drive, wherein the first side rail includes a distal end having a distally-opening slot configured to receive the rigid structure as the disk drive assembly advances to the fully installed position.
